(19) United States
(12) Patent Application Publication
(10) Pub. No.: US 2026/0305335 A1
(43) Pub. Date: Oct. 1, 2026

(54) POWER SEMICONDUCTOR MODULE AND METHOD OF MANUFACTURING THE SAME

(71) Applicant: Infineon Technologies AG, Neubiberg (DE)

(72) Inventors: Andre Uhlemann, Warstein (DE); Edward Fürgut, Dasing (DE); Andreas Grassmann, Sinzing (DE); Thorsten Schorn, Erwitte (DE); Philipp Bräutigam, Warstein-Hirschberg (DE); Florian Dreps, Paderborn (DE)

(21) Appl. No.: 19/629,601

(22) Filed: Mar. 26, 2026

(30) Foreign Application Priority Data
Mar. 28, 2025 (DE) 102025112207.5
Nov. 27, 2025 (DE) 102025149425.8
Mar. 10, 2026 (DE) 102026109785.5

(51) Int. Cl. H10W 40/20; H10W 40/22; H10W 40/25; H10W 40/40; H10W 70/05; H10W 70/60; H10W 70/65; H10W 70/66; H10W 70/692; H10D 80/20

(52) U.S. Cl. CPC H10W 40/235; H10W 40/22; H10W 40/226; H10W 40/233; H10W 40/237; H10W 40/255; H10W 40/40; H10W 70/05; H10W 70/611; H10W 70/658; H10W 70/66; H10W 70/692; H10D 80/251

(57) ABSTRACT

The present disclosure relates to a power semiconductor module suitable for forming a joint with a plastic cooler. The power semiconductor module includes a carrier having a metal layer forming an outer surface of the carrier. The metal layer includes an inner region and an outer region. The metal layer in the outer region has a roughness in a range of 0.1 mm to 1.0 mm.

### TECHNICAL FIELD

The present disclosure relates to a power semiconductor module, in particular to a power semiconductor module for use with a plastic cooler.

### BACKGROUND

Many different applications such as automotive and industrial applications utilize power semiconductor modules. During operation the power semiconductor modules may generate a considerable amount of heat, such that it may be necessary to provide dedicated cooling means for dissipating this heat. Wherein aluminum coolers are commonly used in a large variety of applications, the usage of plastic coolers has become more and more popular. One method to mount a power semiconductor module to a plastic cooler is the so-called heat stacking method in which a metallic joining partner is heated, e.g. inductively, to melt superficial layers of the plastic joining partner to form a thermoplastic joint. However, since a power semiconductor module comprises thermal sensitive components and the contained circuitry may only withstand limited temperatures a metallic joining partner on the power semiconductor module side should only be heated up as localized as possible, e.g. with controlled temperature spreading. On the other hand, the thermoplastic joint between power semiconductor module and plastic cooler must be robust and strong in order to seal a coolant within the plastic cooler and withstand the thermal changes during operation. A fragile thermoplastic joint may lead to leakage of the coolant or even detachment from the cooler which may lead to inefficient performance of the power semiconductor module or even failure during operation.

There is a need for an improved way to mount and seal a power semiconductor module onto a plastic cooler.

### SUMMARY

The present disclosure relates to a power semiconductor module suitable for forming a joint with a plastic cooler. The power semiconductor module comprises: a carrier having a metal layer forming an outer surface of the carrier, wherein the metal layer comprises an inner region and an outer region, wherein the metal layer in the outer region has a roughness Ra in a range of 0.1 mm to 1.0 mm.

A further aspect relates to a power semiconductor module comprising an electrically insulating layer comprising a first surface. A first metal layer is arranged over the first surface of the electrically insulating layer. The first metal layer comprises a first plurality of trenches and a second plurality of trenches. The first plurality of trenches extends inwardly from a first edge of the first metal layer. The second plurality of trenches extends inwardly from a second edge of the first metal layer, the second edge being orthogonal to the first edge.

A further aspect relates to a method for producing a power semiconductor module comprising: providing an electrically insulating layer comprising a first surface, arranging a first metal layer over the first surface of the electrically insulating layer, forming a first plurality of trenches in the first metal layer extending inwardly from a first edge of the first metal layer, forming a second plurality of trenches in the first metal layer extending inwardly from a second edge of the first metal layer, wherein the second edge is orthogonal to the first edge.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates an example of a power semiconductor module having a roughened outer region in a bottom metal layer.

FIG. 2 illustrates an electronic system having a plastic cooler mounted to the roughened outer region in the bottom metal layer of the power semiconductor module of FIG. 1.

FIG. 3 illustrates a further example of a power semiconductor module having a plurality of grooves in an outer region in a bottom metal layer.

FIG. 4 illustrates an example of a section of an outer region in a bottom metal layer.

FIG. 5 illustrates a further example of a power semiconductor module having a top metal layer and a bottom metal layer with different widths.

FIGS. 6 and 7 illustrate a top view and a cross-section of an example of a power semiconductor module having a plurality of trenches in a top metal layer of a substrate respectively. The cross-section in FIG. 7 is shown along a line AA’ of FIG. 6.

FIG. 8 illustrates a cross-section of a further example of a power semiconductor module having a recess in a bottom metal layer of a substrate.

FIG. 9 shows a method for forming a substrate having plurality of trenches on a top metal layer of a substrate.

FIG. 10 illustrates an example of a further example of an electronic system having a metallic structure exposed from a plastic cooler.

FIG. 11 illustrates a further example of an electronic system, having a helical spring exposed from a plastic cooler.

FIG. 12 illustrates a further example of an electronic system having a via protruding through an electrically isolating layer of a substrate.

FIG. 13 illustrates a further example of an electronic system having a contact layer between a substrate and a plastic cooler.

FIG. 14 illustrates a further example of an electronic system having a metallic structure electrically coupled with an inlay or bushing integrated in a plastic cooler.

FIG. 15 illustrates an example of an electronic system having a metallic structure protruding from a plastic cooler and being inserted into rivets on the bottom metal layer of a substrate.

FIG. 16 illustrates a further example of a power semiconductor module and an electronic system comprising this power semiconductor module, wherein the power semiconductor module is built of semiconductor dies embedded inside a printed circuit board (PCB) as carrier and the PCB is connected to the plastic cooler.

FIG. 17 illustrates a further example of a power semiconductor module and an electronic system comprising this power semiconductor module, wherein the power semiconductor module is built onto a baseplate as carrier which is connected to the plastic cooler.

FIG. 18 illustrates a further example of a power semiconductor module and an electronic system comprising this power semiconductor module, wherein the power semiconductor module is built onto a vapor chamber as carrier and the vapor chamber is connected to the plastic cooler.

FIGS. 19a (top view) and 19b (cross-section view) illustrate a further example of a power semiconductor module and an electronic systems comprising this power semiconductor module, wherein the power semiconductor module is built onto a heat pipe as carrier and the heat pipe is connected to the plastic cooler.

### DETAILED DESCRIPTION

The present disclosure relates to power semiconductor modules for mounting onto a plastic cooler, wherein a dedicated design of the power semiconductor module’s carrier enables an efficient and robust thermoplastic joint between the carrier and the plastic cooler, e.g. via heat stacking.

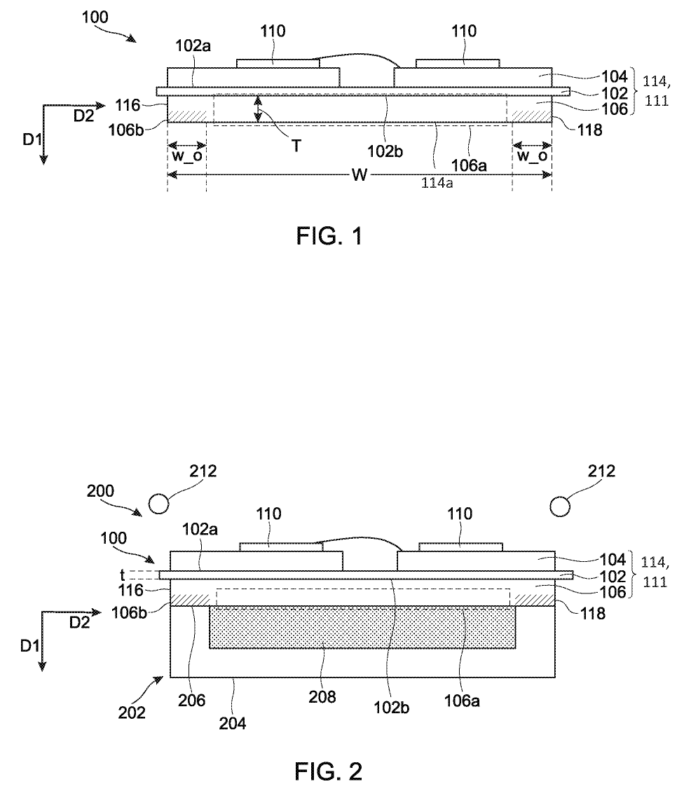

FIG. 1 shows an example of a power semiconductor module 100. The power semiconductor module 100 has a carrier 114 having a metal layer 106 forming an outer surface 114a of the carrier 114. The metal layer 106 has an inner region 106a and an outer region 106b. The metal layer 106 in the outer region 106b has a roughness Ra in a range of 0.1 mm to 1.0 mm. The carrier 114 can be any kind of carrier suitable for carrying semiconductor chips in or on the carrier 114. The carrier 114 may consist of the metal forming the metal layer or may comprise a plurality of layers, conducting and non-conducting. Several examples for the carrier 114 will be described in the following examples.

According to a first example, the carrier 114 shown in FIG. 1 may be an insulative substrate 111, e.g. but not limited to a direct copper bonded substrate (DCB) or an active metal brazed substrate (AMB) etc. The carrier 114 in this example has an electrically insulating layer 102, a top metal layer 104 and a bottom metal layer 106. The top metal layer 104 is arranged over a top surface 102a of the electrically insulating layer 102 and the bottom metal layer 106 is arranged over a bottom surface 102b of the electrically insulating layer 102 opposite to the top surface 102a. The layers 104, 106 are directly bonded onto the respective surface 102a, 102b of the electrically insulating layer 102. The outer surface of the bottom metal layer 106 in this example forms the outer surface 114a of the carrier 114. The bottom metal layer 106 in the outer region 106b is roughened, resulting in a surface roughness Ra in a range of 0.1 mm to 1 mm, or 0.2 mm to 0.8 mm.

The electrically insulating layer 102 is thermally conductive and may comprise aluminum oxide, silicon nitride or aluminum nitride. The layers 104, 106 may comprise aluminum.

The bottom metal layer 106 has a uniform thickness T in the inner region 106a whereas the bottom metal layer 106 has a varying thickness in the outer region 106b. The thickness of the bottom metal layer 106 in the inner region 106a and in the outer region 106b is measured in a direction D1 orthogonal to the second surface 102b of the electrically insulating layer 102. The thickness T of the bottom metal layer 106 in the inner region 106a may be between 0.3 mm to 3 mm. The top metal layer 104 may have a thickness measured in the direction D1. The thickness of the top metal layer 104 may be same or different than the thickness T of the bottom metal layer 106 in the inner region 106a. In one example, the thickness of the top metal layer 104 may be about 1 mm and the thickness T of the bottom metal layer 106 may be about 3 mm.

The bottom metal layer 106 is a continuous metal layer and the inner region 106a and the outer region 106b are distinct regions in the bottom metal layer 106. The surface of the bottom metal layer 106 in the inner region 106a is smooth compared to the bottom metal layer 106 in the outer region 106b. In the outer region 106b, the bottom metal layer 106 may have a surface roughness Ra in a range of 0.1 mm to 1 mm, in particular 0.2 mm to 0.8 mm, in particular 0.3 mm to 0.6 mm. The surface roughness Ra may be up to 80% or 70% or 60% or 50% of the thickness T of the bottom metal layer 106 in the inner region 106a. The surface roughness Ra is measure of the surface texture. The surface roughness Ra is an average distance between the peaks and valleys in outer region 106b in the bottom metal layer 106 and is measured in the direction D1. The surface roughness Ra of the bottom metal layer 106 in the outer region 106b is smaller than the thickness T of the bottom metal layer 106 in the inner region 106a i.e. the bottom metal layer 106 in the outer region 106b is continuous. The bottom metal layer 106 in the outer region 106b may be treated by a laser ablation, grinding or chemical etching to roughen its surface in the outer region 106b. The roughness of the bottom metal layer 106 in the outer region 106b may be uniform or non-uniform.

The bottom metal layer 106 has a width W measured in a direction D2 parallel to the second surface 102b of the electrically insulating layer 102. The width W of the bottom metal layer 106 is measured between two opposing edges 116, 118 of the bottom metal layer 106. The outer region 106b in the bottom metal layer 106 extends inwardly from the edge 116, 118. The outer region 106b in the bottom metal layer 106 may have a width w_o measured from the edge 116, 118 of the bottom metal layer 106 in the direction D2 as shown in FIG. 1. The width w_o of the outer region 106b is up to 10% or 20% or 30% of the width W of the bottom metal layer 106. The width w_o of the outer region 106b in the bottom metal layer 106 may be between 1 mm to 8 mm, in particular 2 mm to 6 mm, in particular 3 mm to 5 mm.

The power semiconductor module 100 may have an electrical circuit arranged over the top metal layer 104 comprising one or more semiconductor dies 110, resistors, capacitors, etc. The electrical circuit may form an inverter circuit, e.g. but not limited to a full bridge circuit or a half-bridge circuit.

The outer surface 114a of the carrier 114 is suitable for forming a joint, in particular a direct joint with a plastic cooler 202 as depicted in FIG. 2 which illustrates an electronic system 200 having the power semiconductor module 100 of FIG. 1 and the plastic cooler 202. In particular, the bottom metal layer 106 in the outer region 106b is suitable for forming the direct joint with the plastic cooler 202. The plastic cooler 202 has a frame 204 made of a thermoplastic material or a thermoset material which has a melting temperature in the range of 260°-320°C, in particular 280°-300°C. The frame 204 is open from one side i.e., has an open circumferential end 206. The plastic cooler 202 is mounted to the power semiconductor module 100 by a heat stacking process using a heat stacking tool. The substrate 111 may be heated inductively up to the melting temperature of the frame 204 i.e., 300°C by an induction loop 212 of the heat stacking tool arranged around and above the substrate 111. An AC current in a frequency range of 2 GHz to 5 GHz may be passed through the induction loop 212, which generates a varying magnetic field. The varying magnetic field penetrates the top metal layer 104 and thus creates eddy currents in the top metal layer 104. The eddy currents are dissipated in form of heat and the heat is transferred to the bottom metal layer 106 through the electrically insulating layer 102. The degree of heating in the substrate 111 can be controlled by the frequency of the AC current. The plastic cooler 202 is pressed to bottom metal layer 106 in the outer region 106b while heating the substrate 111. In particular, the open circumferential end 206 of the frame 204 of the plastic cooler 202 is pressed to the bottom metal layer 106 in the outer region 106b. Upon pressing, the open circumferential end 206 of the frame 204 is in contact with the heated bottom metal layer 106 in the outer region 106b and hence is melted. As a result, a direct thermoplastic joint between the open circumferential end 206 of the frame 204 and the bottom metal layer 106 in the outer region 106b is formed after the frame 204 of the plastic cooler 202 cools down. The above described process can analogously be performed for any other carrier having a metal layer 106 at its outer surface. Eventually, it is required/preferred to only heat up relevant parts of the outer region 106b of the metal layer 106.

The surface roughness Ra of the bottom metal layer 106 in the outer region 106b increases a surface area of the bottom metal layer 106 in the outer region 106b. This provides more contact surface between the open circumferential end 206 of the frame 204 and the bottom metal layer 106. While pressing the open circumferential end 206 to the bottom metal layer 106, the thermoplastic material or the thermoset material of the frame 204 can spread into crevices and valleys of the rough the bottom metal layer 106 in the outer region 106b providing a mechanical interlock between the plastic cooler 202 and the bottom metal layer 106 in the outer region 106b. The surface roughness Ra of the bottom metal layer 106 increases the strength and the robustness of thermoplastic joint.

A thickness t of the electrically insulating layer 102 may be equal to or smaller than the thickness T of the bottom metal layer 106 in the inner region 106a for efficient heat transfer between the top 104 and the bottom 106 metal layer. Furthermore, a ratio of a thickness t of the electrically insulating layer 102 and the thickness T of the bottom metal layer 106 in the inner region 106a may be in a range of 0.5 to 1. The thickness t of the electrically insulating layer 102 is measured in the direction D1 as indicated in FIG. 2.

During operation, a coolant 208 may flow through the plastic cooler 202. The coolant 208 may be, e.g. glycol, water, coolant oils or other liquids, or ambient air, hydrogen, helium, etc. The coolant 208 is in direct contact with the bottom metal layer 106 and thus may provide improved thermal performance, increased power density, reduced thermal stress, simplified design, and cost-effectiveness by allowing for more efficient heat transfer and eliminating the need for intermediate cooling components.

As the open circumferential end 206 is mounted directly onto the carrier 114, the coolant 208 is only in contact with the outer surface 114a of the carrier 114. In this case, the open circumferential end 206 is mounted onto the bottom metal layer 106 in the outer region 106b, the coolant 208 is only in contact with the bottom metal layer 106 in the inner region 106a. Furthermore, the bottom metal layer 106 further comprises a corrosion-resistant metal coating on the bottom metal layer 106 in the inner region 106a to prevent the oxidation of the bottom metal layer 106 due to the coolant 208. The corrosion-resistant metal coating may comprise e.g., but not limited to a layer of zinc or nickel etc. Therefore, the inner region 106a in the bottom metal layer 106 is not roughened to keep the corrosion-resistant layer intact.

The power semiconductor module 100 may have metallic cooling structures like pin fins or metallic ribbons bonded onto outer surface 114a of the carrier 114. For instance, the metallic cooling structure may be bonded onto the bottom metal layer 106 in the inner region 106a. Metallic cooling structures increase an effective surface area of the bottom metal layer 106 for heat dissipation. Furthermore, the metallic cooling structure may increase turbulence in the coolant 208 enhancing the heat dissipation.

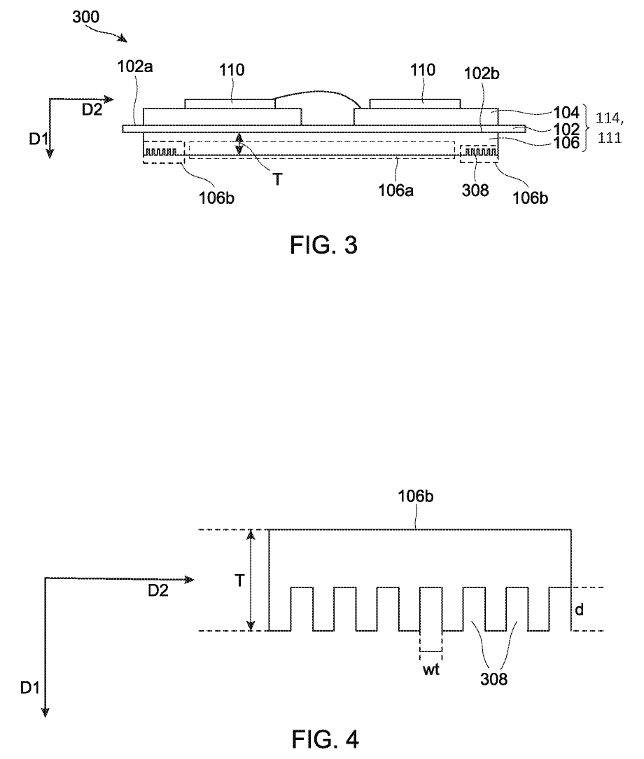

FIG. 3 illustrates a further example of a power semiconductor module 300. The power semiconductor module 300 may include some or all features of the power semiconductor module 100 of FIG. 1 and therefore will be discussed in regard of differences only. The metal layer 106 of the carrier 114 i.e., the bottom metal layer 106 has a plurality of grooves 308 roughening the bottom metal layer 106 in the outer region 106b. In contrast to the pure roughening of the metal surface, the plurality of grooves 308 are formed in a controlled manner such that directions as well as dimensions e.g., a width wt and a depth d of each groove of the plurality of grooves 308 are deterministic. The plurality of grooves 308 may be formed by laser ablation or chemical etching. The depth d of each groove of the plurality of grooves 308 is measured in the direction D1 and the width wt of each groove of the plurality of grooves 308 is measured in the direction D2 as shown in FIG. 4, the outer region 106b in the bottom metal layer 106.

For the power semiconductor module 300 as shown in FIG. 3, the surface roughness Ra of the bottom metal layer 106 is given by the depth d of each groove of the plurality of grooves 308 i.e., in a range of 0.1 mm to 1 mm, in particular 0.2 mm to 0.8 mm, in particular 0.3 mm to 0.6 mm. The depth d of each groove of the plurality of grooves 308 may be same or different. Each groove of the plurality of grooves 308 may be extend along the direction D2 within the outer region 106b in the bottom metal layer 106

In one example, each groove of the plurality of grooves 308 may be circumferential.

The thickness T of the bottom metal layer 106 in the inner region 106a is larger than the depth d of each groove 308 of the plurality of grooves 308 i.e., the grooves do not go all the way down to the electrically insulating layer 102.

The power semiconductor module 300 may be mounted onto a plastic cooler 202 analog to the power semiconductor module 100 as disclosed in the FIG. 2. The plurality of grooves 308 may be equidistantly spaced i.e., a distance between the grooves is same. Thus, the plurality of grooves 308 provides a consistent texture which may lead to a uniform thermoplastic joint between the plastic cooler 202 and the bottom metal layer 106. The equidistantly spaced grooves 308 can reduce thermomechanical stress in the thermoplastic joint caused by different thermal expansion coefficients of the plastic cooler 202 and the substrate 111 by distributing the stress evenly among the thermoplastic joint. Thus, the risk of breaking the thermoplastic joint may be reduced.

The depth d of each groove of the plurality of grooves 308 may be larger than the width wt of each groove of the plurality of grooves 308. The thermoplastic material or thermoset material of the plastic cooler 202 can be pressed deep into the plurality of grooves 308 further enhancing the strength of the thermoplastic joint.

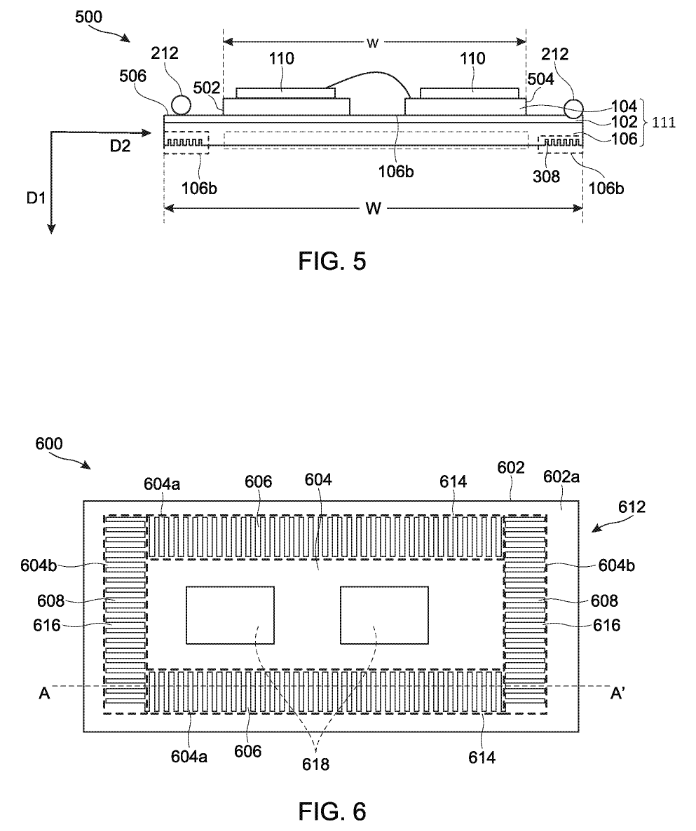

FIG. 5 illustrates a further example of a power semiconductor module 500. The power semiconductor module 500 may include some or all features of the power semiconductor module 300 of FIG. 3. The top metal layer 104 and the bottom metal layer 106 of the substrate 111 have different widths. The bottom metal layer 106 has the width W and the top metal layer 104 has a width w smaller than the width W of the bottom metal layer 106. The width w of the top metal layer 104 is measured between opposing outermost edges 502, 504 of the top metal layer 104 in the direction D2. The width w of the top metal layer 104 may be up to 10% or 30% smaller than the width W of the bottom metal layer 106. The top metal layer 104 is retracted from the edges 502, 504 compared to the bottom metal layer 106 forming an exposed top edge portion 506 of the substrate 111 having a width between 1 mm to 10 mm in particular 2 mm to 5 mm measured in the direction D2.

The exposed top edge portion 506 of the substrate 111 and the outer region 106b in the bottom metal layer 106 may overlap. The top metal layer 104 overlaps with the inner region 106a in the bottom metal layer 106 only. As described herein above, during heat staking the substrate 111 can be heated inductively. The induction loop 212 of the heat stacking tool may be arranged at the exposed top edge portion 506 of the substrate 111. Since in this example there is no top metal layer in the exposed top edge portion 506, the magnetic field will go through the electrically insulating layer 102 and penetrate the bottom metal layer 106 in particular, the outer region 106b, and will induce eddy currents directly in the bottom metal layer 106. This may increase the efficiency of heat generation in the bottom metal layer 106 and thus make the heat stacking process even more efficient and faster.

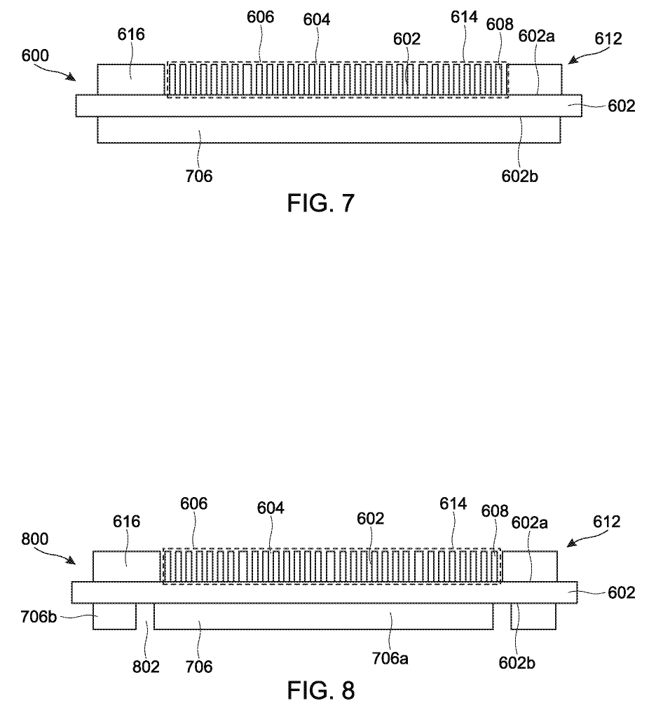

FIGS. 6 and 7 illustrate a top view and a cross-section, respectively, of an example of a power semiconductor module 600. The cross-section of the power semiconductor module 600 in FIG. 7 is along a line AA’ of FIG. 6. The power semiconductor module 600 has a substrate 612 having an electrically insulating layer 602 and a top metal layer 604 arranged over a top surface 602a of the electrically insulating layer 602. The substrate 612 may further comprise a bottom metal layer 706 arranged over a bottom surface 602b of the electrically insulating layer 602 opposite to the top surface 602a as shown in FIG. 7. The electrically insulating layer 602 is thermally conductive and may comprise aluminum oxide, silicon nitride or aluminum nitride. The metal layers 604 and 706 may comprise aluminum or copper or an alloy thereof. One or more semiconductors dies 618 may be mounted on the top metal layer 604 inter alia to form an electrical circuit. The electrical circuit may form an inverter circuit, e.g. but not limited to a full bridge circuit or a half-bridge circuit.

As shown in FIG. 6, the top metal layer 604 is provided with a first plurality of trenches 606 extending inwardly from a first edge 604a of the top metal layer 604 in a first edge portion 614 of the top metal layer 604. Similarly, the top metal layer 604 has a second plurality of trenches 608 extending inwardly from a second edge 604b of the top metal layer 604 in a second edge portion 616 of the top metal layer 604. The second edge 604b of the top metal layer 604 is orthogonal to the first edge 604a. Unlike the grooves in the previous example, the trenches 606, 608 go all the way down to the electrically insulating layer 602.

The power semiconductor module 600 may be mounted onto a plastic cooler analog to the power semiconductor module 100 as disclosed in FIG. 2.

Upon mounting the substrate 612 onto the plastic cooler via heat staking a varying magnetic field may generate eddy current in the edge portions 614 and 616 of the top metal layer 604 which is provided with the plurality of trenches 606, 608. The varying magnetic field is concentrated around the edge portions 614, 616 of the top metal layer 604. The first 606 and the second 608 plurality of trenches disrupt the flow of eddy currents in the edge portions 614, 616 of the top metal layer 604. Hence, the amount of eddy current in the top metal layer 604 is suppressed in the edge portions 614, 616 and reduces the heating up of the top metal layer 604 compared to a top metal layer with edge portions without a plurality of trenches. Furthermore, the plurality of trenches 606 and 608 expose the electrically insulating layer 602 from the top metal layer 604 in the edge portions 614, 616 of the top metal layer 604. The field concentrators may be provided above the plurality of trenches 606 and 608 to direct the varying magnetic field to the exposed electrically insulating layer 602 such that the varying magnetic field can pass through the electrically insulating layer 602 and penetrate the bottom metal layer 706. Thus, the eddy currents are generated in bottom metal layer 706 and the bottom metal layer 706 can be directly heated to mount the plastic cooler to the bottom metal layer 706 without the risk of exposing circuitry implemented on the top metal layer 604 to heat. Further, by directly heating the bottom metal layer 706, the heat stacking process can be made even more efficient and faster.

The field concentrator may be cylindrical, cuboidal in shape and may have a ferrite core or a laminated steel core.

The trenches of the first plurality of trenches 606 are spaced apart along the first edge 604a of the top metal layer 604 by a first distance. The trenches of the second plurality of trenches 608 are spaced apart along the second edge 604b of the top metal layer 604 by a second distance. The first distance may be in a range of 0.1 mm to 10 mm, in particular 0.5 mm to 8 mm, in particular 1 mm to 5 mm. A width of each trench of the first plurality of trenches 606 may be in a range of 0.1 mm to 1 mm, in particular between 0.2 to 0.8 mm, in particular 0.5 mm to 0.7 mm. Similarly, the second distance may be in a range of 0.1 mm to 10 mm, in particular 0.5 mm to 8 mm, in particular 1 mm to 5 mm. The first distance may be equal to the second distance. A width of each trench of the second plurality of trenches 608 may be in a range of 0.1 mm to 1 mm, in particular 0.2 to 0.8 mm, in particular 0.5 mm to 0.7 mm. The first distance, the second distance, the width of each trench of the first plurality of trenches 606 and the width of each trench of the second plurality of trenches 608 are measured in a direction parallel to the top surface 602a of the electrically insulating layer 602.

FIG. 8 shows a cross-section of a further example of a power semiconductor module 800. The power semiconductor module 800 may include some or all features of the power semiconductor module 600 shown in FIG. 6 and therefore will be discussed in regard of differences only. The bottom metal layer 706 may have a circumferential recess 802 which separates an inner region 706a from an outer region 706b in the bottom metal layer 706. The bottom metal layer 706 in the inner region 706a overlaps with the electrical circuitry on the top metal layer 604. When the bottom metal layer 706 is heated more than the top metal layer 604, the circumferential recess 802 obstructs the heat distribution between the inner region 706a and the outer region 706b in the bottom metal layer 706, thus the heat transfer from the inner region 706a in the bottom metal layer 706 to electrical circuitry on the top metal layer 604 may be further reduced.

The outer region 706b of the bottom metal layer 706 may optionally have a surface roughness Ra in range of 0.1 mm to 1.0 mm, in particular 0.2 mm to 0.8 mm, in particular 0.3 mm to 0.6 mm. The surface roughness Ra increases the strength of the thermoplastic joint between the plastic cooler and the bottom metal layer 706 as described in reference to FIGS. 1 to 5. The surface roughness Ra may be in the range of

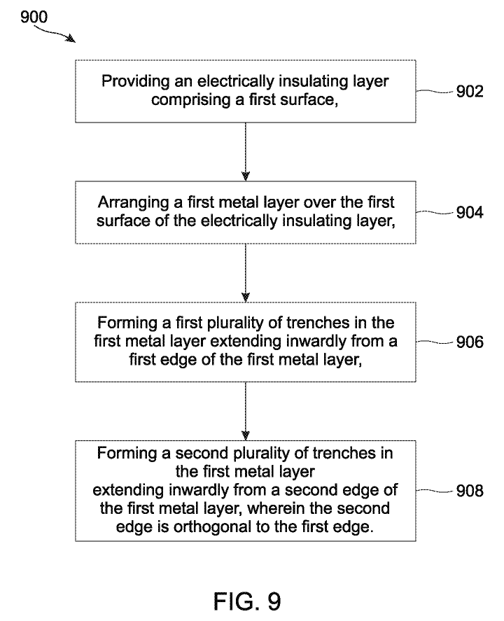

FIG. 9 shows a method 900 for forming a substrate as described in reference to FIGS. 6 to 8. The method 900 involves providing 902 an electrically insulating layer comprising a first surface. The method 900 further involves arranging 904 a first metal layer over the first surface of the electrically insulating layer. In another step, a first plurality of trenches are formed 906 in the first metal layer extending inwardly from a first edge of the first metal layer. In a further step, a second plurality of trenches are formed 908 in the first metal layer extending inwardly from a second edge of the first metal layer, wherein the second edge is orthogonal to the first edge.

The first plurality of trenches and the second plurality of trenches are formed by etching parts of the first metal layer and parts of the second metal layer. The etching can be achieved by e.g., but not limited to laser etching or chemical etching.

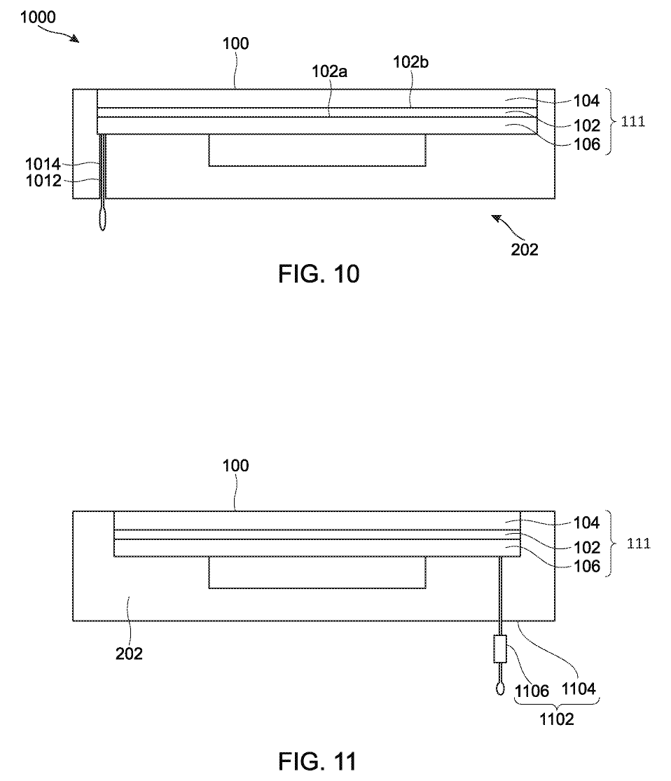

FIG. 10 shows an example of an electronic system 1000 comprising a power semiconductor module 100 and the plastic cooler 202. The power semiconductor module in FIG. 10 may be any of the power semiconductor module of FIGS. 1, 3, 5 or 6-8. As an example, the power semiconductor module 100 of FIG. 1 is used in FIG. 10. For simplicity, only the substrate 111 of the power semiconductor module 100 is shown in FIG. 10. The plastic cooler 202 may be mounted to the bottom metal layer 106 by e.g., heat-stacking, screwing or sealing. The plastic cooler 202 hermetically seals the bottom metal layer 106 of the substrate 111. The power semiconductor module further has a metallic structure 1012 electrically coupled with the bottom metal layer 106, and at least a part of the metallic structure 1012 is exposed from the plastic cooler 202.

When the power semiconductor module 100 is operated, the metallic structure 1012 may be used to ground the bottom metal layer 106 and thus avoid that a displacement current created in the electrically insulating layer 102 due to different voltages region on to the top metal layer 104 to lead to critical electromagnetic interference in the power semiconductor module 100.

The metallic structure 1012 may be a pin or a wire as shown in FIG. 10. The pin or the wire can be soldered, sintered or welded on the bottom metal layer 106. The plastic cooler 202 has a hole/opening 1014 and the pin or the wire passes through the hole 1014 of the plastic cooler 202. The pin or the wire 1012 may be monolithically formed in the bottom metal layer 106.

FIGS. 11-13 show further examples of the metallic structure.

As indicated in FIG. 11, the metallic structure 1102 comprises a helical spring 1104 and a pin 1106. The pin 1106 is inserted into the helical spring 1104. The helical spring 1104 can act as an induction loop, heating the pin 1106 inductively, before pressing the pin through the plastic cooler 202 to electrically contact the bottom metal layer 106. A part of the pin 1106 remains exposed from the plastic cooler 202 and can be used to ground the bottom metal layer 106 from outside.

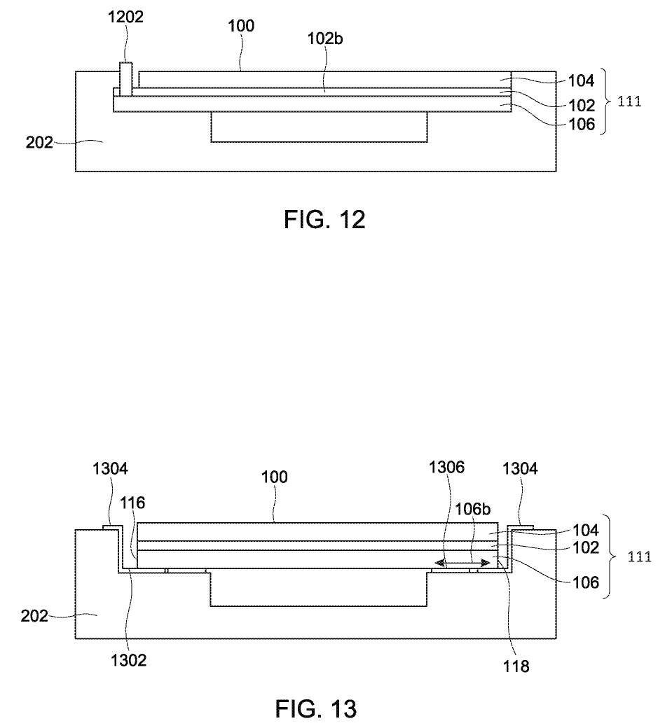

As indicated in FIG. 12, the metallic structure 1202 may be a via. The via protrudes from the bottom metal layer 106 through the electrically insulating layer 102, providing a contact on the side of the top metal layer 104. The contact is electrically isolated from the top metal layer 104. Thus, the bottom metal layer 106 can be grounded from the top through the via.

As indicated in FIG. 13, the metallic structure 1302 may be a contact layer. The plastic cooler 202 is mounted to the outer region 106b of the bottom metal layer 106 by heat stacking as described herein. The thermoplastic joint between the plastic cooler 202 and the bottom metal layer 106 is formed in a bonding region 1306 of the bottom metal layer 106 in the outer region 106b. The bonding region 1306 is slightly inward from the edge 116, 118 of the bottom metal layer 106. The contact layer is arranged between the bottom metal layer 106 and the plastic cooler 202. In particular, the contact layer may be integrated into the plastic cooler 202 such that when the substrate 111 is pressed onto the plastic cooler 202, the bottom metal layer 106 and the contact layer are electrically and mechanically coupled via a press contact around the edge 116, 118 of the bottom metal layer 106. Further, the contact layer is outside of the bonding region 1306, extends outside of the plastic cooler 202 and provides an electrical contact 1304 outside of the plastic cooler 202. The contact layer is electrically isolated from the top metal layer 104. The electrical contact 1304 can be used to ground the bottom metal layer 106.

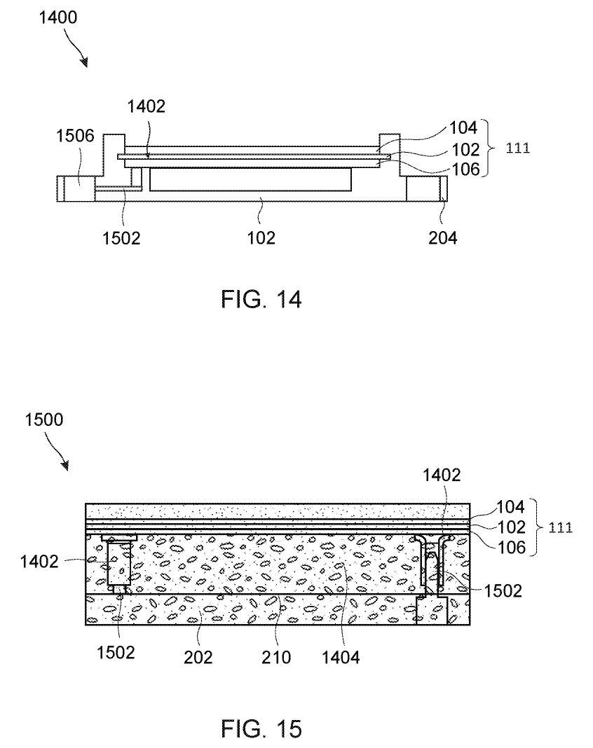

FIG. 14 shows a further alternative to ground the backside of the substrate 111 integrated into plastic cooler 202. The electronic system 1400 may include some or all features of the electronic system 1000 and will be discussed in regard to differences only. The metallic structure 1502 is electrically coupled with the bottom metal layer 106 via a rivet 1402 mounted onto the bottom metal layer 106 of the substrate 111. The rivet 1402 serves as a backside contact for the bottom metal later 106 and consequently, the rivet 1402 may be used to ground the bottom metal layer 106 via the metallic structure 1502. The metallic structure 1502 may be connected to a bushing or an inlay 1506, integrated within the frame 204 of the plastic cooler 202. In particular, the metallic structure 1502 may extend parallel to the bottom metal layer 106 within the frame 204 of the plastic cooler 202 and may be connected to bushing or inlay 1506 positioned at the sidewall of the frame 204 of the plastic cooler 202. The bushing or inlay 1506 is exposed from the plastic cooler 202 and thus can be used to ground the bottom metal layer 106 and consequently avoid the displacement current created in the electrically insulating layer 102.

In one example, the inlay or bushing 1506 may be at the bottom wall of the frame 204 of the plastic cooler 202.

FIG. 15 shows a further example of the substrate 111 usable in any of the power semiconductor modules of FIGS. 1, 3, 5 or 6-8. In this example, two or more rivets 1402 are mounted onto the bottom metal layer 106. In the example shown two rivets 1402 are positioned in a diagonal with regard to a center portion of the substrate 111. The center portion of the substrate 111 is within the inner region 106a of the bottom metal layer 106. The rivets 1402 are mounted in the outer region 106b of the bottom metal layer 106 as shown in FIG. 14. However, the rivets 1402 may also be both mounted in the inner region 106a of the bottom metal layer 106 or at least one of the rivets 1402 may be in the outer region 106b of the bottom metal layer 106 and the other rivet 1402 may be mounted in the inner region 106a of the bottom metal layer 106. For positioning and alignment purposes the difference in roughness of the inner region 106a and the outer region 106b of the bottom metal layer 106 is irrelevant. The inner region 106a and the outer region 106b of the bottom metal layer 106 may thus also have the same roughness or be smooth.

In addition to grounding the bottom metal layer 106, rivets 1402 on the bottom metal layer 106 may also be used to align and/or fixate the substrate 111 in the plastic cooler 202. One or more metallic structures 1502 partially embedded in the plastic cooler 202 may protrude on an inner side 210 of the plastic cooler facing the bottom metal layer 106. During assembly of the power semiconductor module onto the plastic cooler 202, each of the one or more metallic structures 1502 is aligned with the respective rivets 1402. When the power semiconductor module, in particular the substrate 111 is pressed onto the plastic cooler 202 as described herein above, the rivets 1402 and the respective one or more metallic structures 1502 interlock. In one example, the rivets 1402 may be hollow-rivet and the metallic structure 1502 may be a pin or a stud which can be inserted into the hollow rivet to form a press-fit connection. As the rivets 1402 and thus the one or more metallic structures 1502 are fixed on their respective positions, misalignment between the substrate 111 and the plastic cooler 202 due to the drifting and tilting of the substrate 111 with respect to the plastic cooler 202 during assembly or operation may be reduced or even avoided.

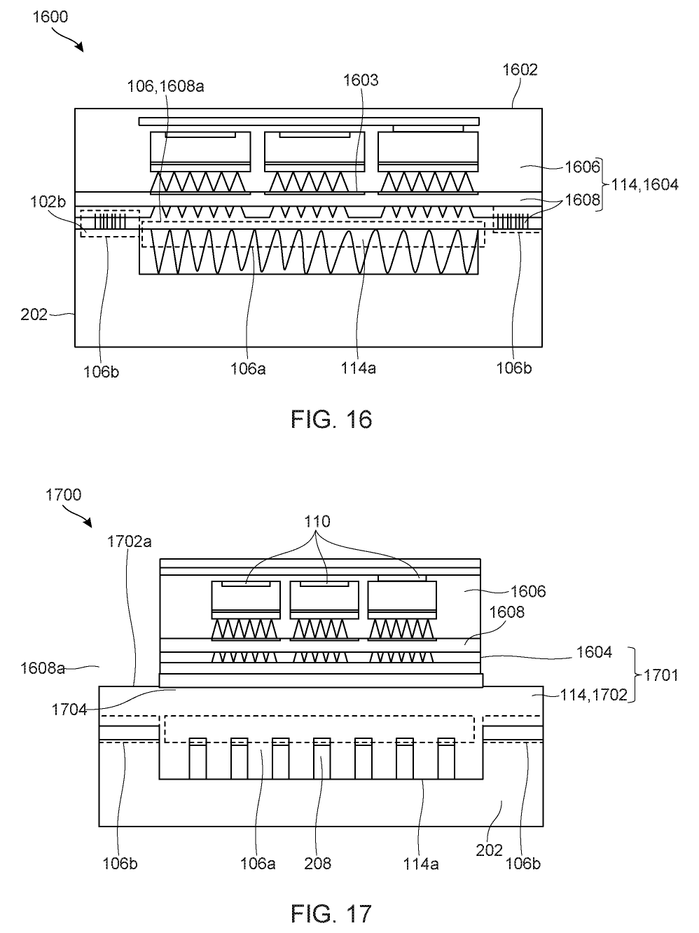

FIG. 16 shows a further example of a power semiconductor module 1602 as well as its integration into an electronic system 1600. The electronic system 1600 may include some or all features of any of the electronic systems described herein above and will be discussed in regard to differences only. The electronic system 1600 includes the power semiconductor module 1602 mounted onto the plastic cooler 202. The power semiconductor module 1602 has a circuit board 1604 as the carrier 114. The circuit board 1604 comprises one or more electrically non-conducting layers 1606 and one or more metal layers 1608. The circuit board 1604 may be a printed circuit board (PCB). The conducting layers may comprise a core layer, such as but not limited to a fiberglass reinforced FR4, as well as one or more electrically non-conductive layers stacked alternatingly with the metal layers on one or both sides of the core layer. Alternatively, the printed circuit board may also be constructed as an insulated metal substrate (IMS). The semiconductor dies 110 may be placed on top of the circuit board 1604 or may be embedded within the circuit board 1604. As shown exemplary in FIG. 16, an outermost metal layer 1608a of a circuit board 1604 may serve as the metal layer 106 of the carrier 114. The outermost metal layer 1608a forms the outer surface 114a of the carrier 114. Optionally, the outermost metal layer 1608a is thermally coupled but electrically isolated from the semiconductor dies 110. For instance, an electrically insulating layer 1603 embedded in the circuit board 1604 and/or the die carrier 1605 of the semiconductor die 1605 may be arranged between the semiconductor die 110 and the outermost metal layer 1608a. Thus, the outermost metal layer 1608a may act as a heat spreader while being electrically inactive. The outermost metal layer 1608a is roughened in the outer region 106b and the plastic cooler 202 is mounted directly onto the outermost metal layer 1608a. The outermost metal layer 1608a in the inner region 106a over which the semiconductor dies 110 are arranged, may be in direct contact with the coolant 208 and thus allowing the heat from the semiconductor dies 110 can be efficiently dissipated. As described for the previous examples, metallic structures may be arranged between the plastic cooler 202 and the outermost metal layer 1608a, for instance to increase the turbulence of the coolant 208.

FIG. 17 shows a further example of a power semiconductor module 1701 as well as its integration into an electronic system 1700. The power semiconductor module 1701 and the electronic system 1700 may include some or all features of the power semiconductor module 1602 and the electronic system 1600 respectively described herein above and will be discussed in regard to differences only. The power semiconductor module 1701 comprises the circuit board 1604 and a baseplate 1702 as the carrier 114. The circuit board 1604 is arranged over the baseplate 1702. For instance, a first surface 1702a of the baseplate 1702 faces the outermost metal layer 1608 of the circuit board. Optionally, an electrically insulating layer 1704 made of e.g. but not limited to a thermal interface material or dielectric material or a ceramic material, may be arranged between the baseplate 1702 and the circuit board 1604. In particular, the electrically insulating layer 1704 may be arranged between the first surface 1702a of baseplate 1702 and the outermost metal layer 1608a of the circuit board. The electrically insulating layer 1704 provides thermal coupling and electrical isolation between the baseplate 1702 and the circuit board 1604. A lower side of the baseplate 1702 facing away from the circuit board 1604 serves as the metal layer 106 of the carrier 114 and the outer surface of the outer wall of the baseplate 1702 is the surface 114a of the carrier 114. The baseplate 1702 is roughened in the outer region 106b and the plastic cooler 202 may be mounted onto the baseplate 1702 in the outer region 106b. The roughening may be achieved by etching, lasering or the base plate may be formed by metal injection molding, thereby creating mirco-holes at least at the outer region 106b to obtain the required roughness. The semiconductor dies 110 may be arranged over the inner region 106a of the baseplate 1702. The coolant 208 may flow through the plastic cooler 202 and may be in direct contact with the baseplate 1702, in particular in the inner region 106a. Thus, the heat from the power semiconductor module 1602, in particular the semiconductor dies 110 can be dissipated.

Optionally, the inner region 106a of the baseplate 1702 may have metallic structures to increase the turbulence of the coolant 208 and thus further enhance the heat dissipation from the power semiconductor module 1602.

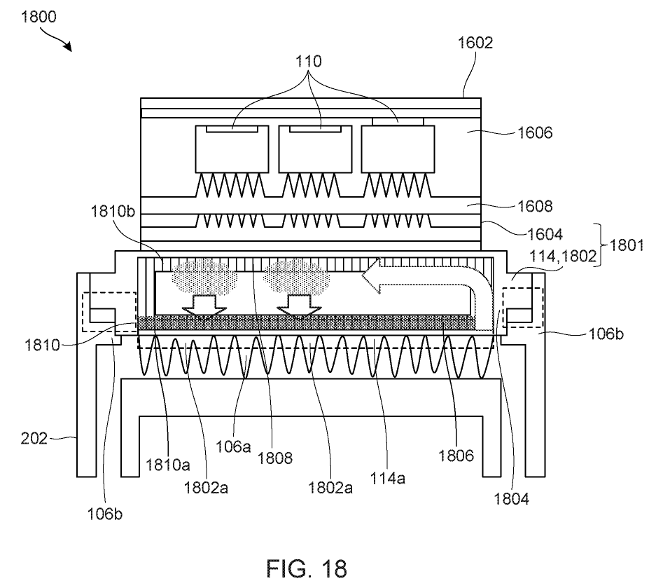

FIG. 18 shows a further example of a power semiconductor module 1801 as well as its integration into an electronic system 1800. The power semiconductor module 1801 and electronic system 1800 may include some or all features of the power semiconductor module 1701 and the electronic system 1700 respectively and will be discussed in regard to differences only. Instead of the baseplate 1702, the power semiconductor module 1602 has a vapor chamber 1802 that serves as the carrier 114. A lower wall 1802a of the vapor chamber 1802 forms the metal layer 106 of the carrier 114 and an outer surface of the lower wall 1802a of the vapor chamber 1802 is the surface 114a of the carrier 114. A lower wall 1802a of the vapor chamber 1802 in the outer region 106b may be roughed and the plastic cooler 202 may be mounted onto the vapor chamber 1802 in the outer region 106b. The circuit board 1604 is arranged over an upper wall 1802b of the vapor chamber 1802 in the inner region 106a. The upper wall 1802b of the vapor chamber 1802 is opposite to the lower wall 1802a. Thus, the upper wall 1802b of the vapor chamber 1802 is thermally coupled with the circuit board 1604 and the lower wall 1802a of the vapor chamber 1802 is thermally coupled with the plastic cooler 202.

The vapor chamber 1802 may have a metal chamber 1804 and a working fluid 1806 and a wick 1808. The working fluid 1806 may be, but is not limited to, water, methanol or ammonia etc. and is contained inside the metal chamber 1804. The metal chamber 1804 is partially filled with the working fluid 1806 leaving some space above the working fluid 1806. The wick 1808 is arranged on an inner surface 1810 of the vapor chamber 1802 and configured to transport the working fluid 1806 by capillary action. The wick 1808 may be formed from a porous metallic material, such as a sintered copper powder, a copper or stainless-steel mesh, or a fibrous metal or ceramic structure.

Due to the mounting orientation of the electronic system 1800, the working fluid 1806 is predominantly located on an inner lower surface 1810a of the vapor chamber 1802 adjacent to the lower wall 1802a. The wick 1808 can transport the working fluid 1806 towards an upper inner surface 1810b of the vapor chamber 1802 opposite to the lower inner surface 1810a of the vapor chamber 1802. The working fluid 1806 utilizes the phase change principle for heat dissipation. During operation, the working fluid 1806 on the region of the upper inner surface 1810b absorbs heat from the circuit board 1604, in particular, the semiconductor dies 110 and vaporizes. The generated vapor spreads within the metal chamber 1804 and flows toward cooler regions, in particular toward the lower inner surface 1810a, where it condenses and releases the absorbed heat. The condensed working fluid 1806 is then returned to the region of the upper inner surface 1810b through the wick 1808, thereby closing the circulation loop.

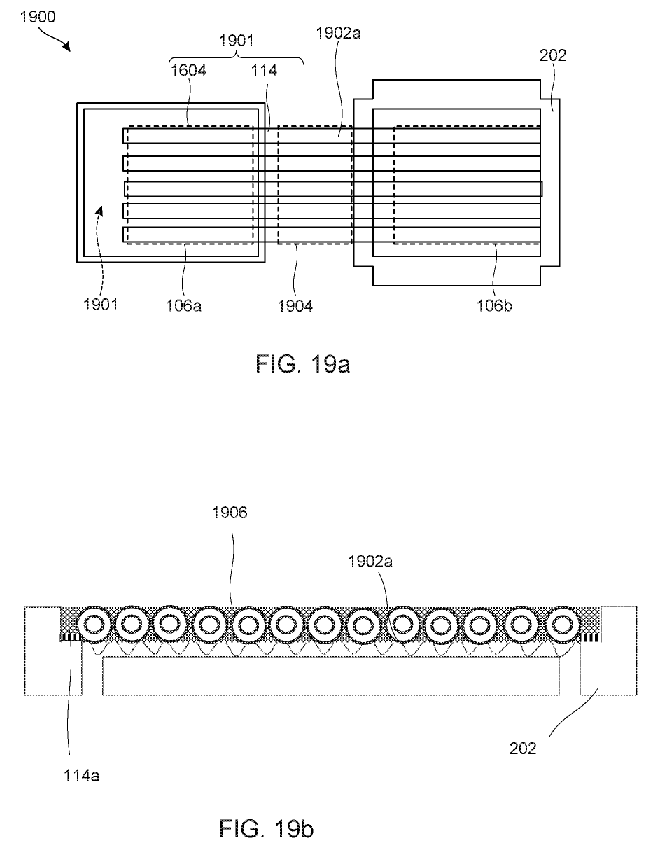

FIG. 19a shows a top view and FIG. 19b shows a cross-section view of a further example of a power semiconductor module 1901 as well as its integration into an electronic system 1900. The power semiconductor module 1901 and electronic system 1900 may include some or all features of the power semiconductor module 1801 and the electronic system 1800 respectively and will be discussed in regard to differences only. Instead of the vapor chamber 1802, the power semiconductor module 1901 has a heat pipe 1902 made of a suitable metal that serves as the carrier 114. An outer wall 1902a of the heat pipe 1902 forms the metal layer 106 of the carrier 114 and an outer surface of the outer wall 1902a of the heat pipe 1902 is the surface 114a of the carrier 114. The inner region 106a and the outer region 106b of the heat pipe 1902 are positioned at lateral opposite ends of the heat pipe 1902 as shown in FIG. 19a and 19b. Optionally, an intermediate region 1904 of the heat pipe 1902 may be positioned between the inner region 106a and the outer region 106b of the heat pipe 1902. The heat pipe 1902 in the outer region 106b is roughened and the plastic cooler 202 may be mounted onto the heat pipe 1902 in this outer region 106b. The circuit board 1604 is arranged over the heat pipe 1902 in the inner region 106a of the heat pipe 1902. Thus, the heat pipe 1902 in the inner region 106a and in the outer region 106b is thermally coupled to the circuit board 1604 and the plastic cooler 202 respectively.

The heat pipe 1902 has a working fluid 1806 arranged inside the heat pipe 1902. The working fluid 1806 absorbs the heat from the circuit board 1604, in particular from the semiconductor dies 110 and the heat is transferred to the outer region 106b of the heat pipe 1902 via the working fluid 1806, where it is further dissipated by the cooling medium in the plastic cooler 202. For instance, the working fluid 1806 may evaporate in the inner region 106a, flow or diffuse toward the outer region 106b, and condense there, enabling an efficient transport of heat from the circuit board 1604 towards the plastic cooler 202. The outer region 106b of the heat pipe 1902 is in direct contact with the cooling medium in the plastic cooler. Surface structures, like pin fins or ribbons may be provided on the outer surface of the outer region 106b of the heat pipe 1902 of within the plastic cooler. The wick (not shown) may optionally be arranged on an inner surface of the heat pipe 1902 to transport the condensed working fluid 1806 from the outer region 106b to the inner region 106a via capillary force.

In the example shown in FIG. 19a and 19b, the heat pipe is constructed as a plurality of pipes interconnected by a common metal casing 1906. It is understood that the heat pipe can be realized in any other way, as long as the lower surface provides a metallic surface with the required roughness that can be joined to the plastic cooler.

In the electronic systems disclosed herein above the improved heat dissipation allows semiconductor dies 110 to be arranged in a compact layout, thus allowing a higher power density, e.g. resulting in a reduced footprint of the power semiconductor module 1602 for a given power class. Instead of a circuit board 1604 the chips may also be mounted onto a leadframe or any other kind of suitable substrate in the examples described herein above.

The semiconductor dies may, for example, be configured as power MISFETs (Metal Insulator Semiconductor Field Effect Transistors), power MOSFETs (Metal Oxide Semiconductor Field Effect Transistors), IGBTs (Insulated Gate Bipolar Transistors), JFETs (Junction Gate Field Effect Transistors), HEMTs (High Electron Mobility Transistors), power bipolar transistors or power diodes such as, e.g. PIN diodes or Schottky diodes.

The semiconductor dies may be manufactured from specific semiconductor material such as, for example, Si, SiC, SiGe, GaAs, GaN, AlGaN, InGaAs, InAlAs, etc., and, furthermore, may contain inorganic and/or organic materials that are not semiconductors. The semiconductor die may be of different types and may be manufactured by different technologies.

The carrier having a metal layer described herein may be a substrate, a baseplate, vapor chamber, a leadframe or a circuit board. By the way of examples, the substrate may be a direct copper bonded (DCB) or active metal brazed (AMB) or insulated metal base (IMB) substrate. One of the metal layers of the substrate may form the metal layer of the carrier. Alternatively, an outer wall of the baseplate or the vapor chamber may form the metal layer of the carrier. By the way of examples, the carrier board may be a printed circuit board or an insulated metal substrate having metal layers at least partially embedded with an encapsulant e.g., a laminate material. One of the metal layers exposed from the encapsulant may serves as the metal layer of the carrier.

The plastic cooler described herein has the frame enclosing a coolant during operation. The plastic cooler is mounted directly onto the outer region of the bottom metal layer by forming a thermoplastic joint between the outer region of the bottom metal layer and the frame of the plastic cooler. During operation the coolant is in direct contact with the bottom metal layer.

The power semiconductor module described herein may have metallic structures bonded directly onto the inner region of the substrate.

The trench or the recess in the respective metal layer exposes the underneath electrically insulating layer from the metal layer, whereas the groove in the metal layer does not expose the underneath electrically insulating layer from the metal layer.

The power semiconductor module may have a housing. The semiconductor dies can be housed within the housing. The housing may be filled with a potting material e.g. but not limited to epoxy resin, silicone gel or polyimide resin etc. The housing may be arranged on the top metal layer and/or on the top surface of the electrically insulating layer. The housing may be sealed on the substrate by an adhesive e.g., epoxy-based adhesive, ceramic adhesive or silicone adhesive or by a thermoplastic bond between the housing and the substrate.

### The following examples pertain to further aspects of the disclosure:

Example 1: A power semiconductor module suitable for forming a joint with a plastic cooler, comprising: a carrier having a metal layer forming an outer surface of the carrier, wherein the metal layer comprises an inner region and an outer region, wherein the metal layer in the outer region has a roughness Ra in a range of 0.1 mm to 1.0 mm.

Example 2: The power semiconductor module according to example 1, wherein the roughness comprises a plurality of grooves.

Example 3: The power semiconductor module according to example 2, wherein the metal layer in the inner region has a uniform thickness larger than a depth of each groove of the plurality of grooves in the outer region in the metal layer, wherein the thickness of the metal layer in the inner region of the metal layer and the depth of each groove of the plurality of grooves are measured in a direction orthogonal to the surface of the carrier.

Example 4: The power semiconductor module according to example 2 or 3, wherein the plurality of grooves are equidistantly spaced.

Example 5: The power semiconductor module according to any one of examples 2 to 4, wherein each groove from the plurality of grooves has a width measured in a direction parallel to the surface of the carrier and wherein the depth of each groove from the plurality of grooves is larger than the width of each groove from the plurality of grooves.

Example 6: The power semiconductor module according to any one of examples 1 to 5, wherein the carrier further comprises an electrically insulating layer and the metal layer is arranged over a surface of the electrically insulating layer.

Example 7: The power semiconductor module according to any of the preceding examples, wherein the metal layer is part of a baseplate, a vapor chamber, or a heat pipe, a metal layer of a circuit board.

Example 8: The power semiconductor module according to any of examples 1 to 5, wherein the carrier comprises: an electrically insulating layer comprising a first surface and an opposing second surface, a first metal layer arranged over the first surface of the electrically insulating layer, wherein the metal layer is a second metal layer arranged over the second surface of the electrically insulating layer, wherein a width of the first metal layer is smaller than a width of the second metal layer, wherein the width of the first and second metal layer is measured in a direction parallel to the second surface of the electrically insulating layer.

Example 9: The power semiconductor module according to example 8, wherein a thickness of the electrically insulating layer is equal to or smaller than the thickness of the metal layer in the inner region, and wherein the thickness of the electrically insulating layer is measured in the direction orthogonal to the second surface of the electrically insulating layer.

Example 10: The power semiconductor module according to example 8 or 9, wherein the first metal layer overlaps only with the second metal layer in the inner region.

Example 11: The power semiconductor module according to any of examples 8 to 10, wherein the first metal layer and the second metal layer comprise aluminum and/or wherein the electrically insulating layer comprises one or more of AlN, SI3N4, or Al2O3.

Example 12: The power semiconductor module according to any of the preceding examples, further comprising: one or more semiconductor dies arranged over the inner region of the metal layer, an encapsulant encapsulating the one or more semiconductor dies.

Example 13: An electronic system comprising: a power semiconductor module according to any one of examples 1 to 12, and a plastic cooler directly pressed onto the outer region of the second metal layer.

Example 14: A power semiconductor module comprising: an electrically insulating layer comprising a first surface, a first metal layer arranged over the first surface of the electrically insulating layer, wherein the first metal layer comprises a first plurality of trenches and a second plurality of trenches, wherein the first plurality of trenches extends inwardly from a first edge of the first metal layer and, wherein the second plurality of trenches extends inwardly from a second edge of the first metal layer, the second edge being orthogonal to the first edge.

Example 15: The power semiconductor module according to example 14, wherein trenches of the first plurality of trenches are spaced apart along the first side of the first metal layer by a first distance and wherein trenches of the second plurality of trenches are spaced apart along the second side of the first metal layer by a second distance.

Example 16: The power semiconductor module according to example 15, wherein the first distance is equal to the second distance.

Example 17: The power semiconductor module according to any one of examples 14 to 16, wherein each trench of the first trench is isolated from each trench of the second trench.

Example 18: The power semiconductor module according to any one of examples 14 to 17, further comprising: a second metal layer arranged over a second surface of the electrically insulating layer opposite to the first surface, wherein the second metal layer comprises a circumferential recess separating an inner region and an outer region in the second metal layer.

Example 19: A method for producing a power semiconductor module comprising: providing an electrically insulating layer comprising a first surface, arranging a first metal layer over the first surface of the electrically insulating layer, forming a first plurality of trenches in the first metal layer extending inwardly from a first edge of the first metal layer, forming a second plurality of trenches in the first metal layer extending inwardly from a second edge of the first metal layer, wherein the second edge is orthogonal to the first edge.

Example 20: The method according to example 19, wherein forming the first plurality of trenches comprises forming the first plurality of trenches by a laser and wherein forming the second plurality of trenches comprises forming the second plurality of trenches by the laser.

Example 21: A power semiconductor module comprising: an electrically insulating layer comprising a first surface, a metal layer arranged over the first surface of the electrically insulating layer, a plastic cooler hermetically enclosing the metal layer, a metallic structure electrically coupled with the metal layer, and wherein at least a part of the metallic structure is exposed from the plastic cooler.

Example 22: The power semiconductor module according to example 21, wherein the plastic cooler comprises a hole and wherein the metallic structure protrudes through the hole of the plastic cooler or wherein the metallic structure comprises a pin and a helical spring or wherein the metallic structure comprises a via through the electrically insulating layer or wherein metallic structure is a contact layer arranged between the metal layer and the plastic cooler and wherein the contact layer provides an electrical contact outside of the plastic cooler.

Example 23: A power semiconductor module comprising: an electrically insulating layer comprising a first surface and an opposing second surface, a first metal layer arranged over the first surface of the electrically insulating layer, a second metal layer arranged over the second surface of the electrically insulating layer, wherein the second metal layer comprises an inner region and an outer region, and a rivet mounted on the second metal layer.

Example 24: An electronic system comprising: a power semiconductor module according to example 23, and a plastic cooler directly pressed onto the outer region of the second metal layer.

Example 25: The electronic system according to example 24, further comprising a metallic structure electrically coupled with the second metal layer, and wherein at least a part of the metallic structure is exposed from the plastic cooler.

Example 26: An electronic system according to example 25, wherein the metallic structure protrudes from an inner surface of the plastic cooler facing the second metal layer, wherein the rivet and the protrusion interlock.

Example 27: The electronic system according to any of the examples 24 to 26, wherein the rivet is a hollow-rivet.

Example 28: The electronic system according to any of the examples 24 to 27, wherein the rivet is a first rivet and further comprises a second rivet diagonally positioned to the first rivet with regard to a center portion of the substrate.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A power semiconductor module, comprising:
a carrier comprising a metal layer forming an outer surface of the carrier,
wherein the metal layer comprises an inner region and an outer region,
wherein the metal layer in the outer region has a roughness Ra in a range of 0.1 mm to 1.0 mm.

2. The power semiconductor module of claim 1, wherein the roughness comprises a plurality of grooves.

3. The power semiconductor module of claim 2, wherein the metal layer in the inner region has a uniform thickness larger than a depth of each groove of the plurality of grooves in the outer region in the metal layer, and wherein the thickness of the metal layer in the inner region of the metal layer and the depth of each groove of the plurality of grooves are measured in a direction orthogonal to the outer surface of the carrier.

4. The power semiconductor module of claim 2, wherein the grooves are equidistantly spaced.

5. The power semiconductor module of claim 2, wherein each groove of the plurality of grooves has a width measured in a direction parallel to the outer surface of the carrier, and wherein the depth of each groove of the plurality of grooves is larger than the width of each groove of the plurality of grooves.

6. The power semiconductor module of claim 1, wherein the carrier further comprises an electrically insulating layer, and wherein the metal layer is arranged over a surface of the electrically insulating layer.

7. The power semiconductor module of claim 1, wherein the metal layer is part of a baseplate, a vapor chamber, a heat pipe or a metal layer of a circuit board.

8. The power semiconductor module of claim 1, wherein the carrier further comprises:
an electrically insulating layer comprising a first surface and an opposing second surface; and
a first metal layer arranged over the first surface of the electrically insulating layer,
wherein the metal layer is a second metal layer arranged over the second surface of the electrically insulating layer,
wherein a width of first metal layer is smaller than a width of the second metal layer,
wherein the width of the first and second metal layer is measured in a direction parallel to the second surface of the electrically insulating layer.

9. The power semiconductor module of claim 8, wherein a thickness of the electrically insulating layer is equal to or smaller than the thickness of the metal layer in the inner region, and wherein the thickness of the electrically insulating layer is measured in the direction orthogonal to the second surface of the electrically insulating layer.

10. The power semiconductor module of claim 8, wherein the first metal layer overlaps only with the second metal layer in the inner region.

11. The power semiconductor module of claim 8, wherein the first metal layer and the second metal layer comprise aluminum and/or wherein the electrically insulating layer comprises one or more of AlN, SI3N4 and Al2O3.

12. The power semiconductor module of claim 1, further comprising:
one or more semiconductor dies arranged over the inner region of the metal layer; and
an encapsulant encapsulating the one or more semiconductor dies.

13. An electronic system, comprising:
the power semiconductor module of claim 1; and
a plastic cooler directly pressed onto the outer region of the metal layer.

14. The electronic system of claim 13, further comprising:
a metallic structure electrically coupled with the metal layer,
wherein at least a part of the metallic structure is exposed from the plastic cooler.

15. The electronic system of claim 14, wherein the plastic cooler comprises a hole and the metallic structure protrudes through the hole of the plastic cooler, or wherein the metallic structure comprises a pin and a helical spring, or wherein the metallic structure comprises a via through the electrically insulating layer, or wherein the metallic structure is a contact layer arranged between the metal layer and the plastic cooler and the contact layer provides an electrical contact outside of the plastic cooler.

16. The electronic system of claim 14, further comprising a rivet mounted on the second metal layer, wherein the metallic structure has a protrusion that protrudes from an inner surface of the plastic cooler facing the second metal layer, and wherein the rivet and the protrusion interlock.

17. The power semiconductor module of claim 16, wherein the rivet is a hollow-rivet.

18. The power semiconductor module of claim 16, wherein the rivet is a first rivet, and wherein the electronic system further comprises a second rivet diagonally positioned to the first rivet with regard to a center portion of the substrate.

19. A power semiconductor module, comprising:
an electrically insulating layer comprising a first surface; and
a first metal layer arranged over the first surface of the electrically insulating layer,
wherein the first metal layer comprises a first plurality of trenches and a second plurality of trenches,
wherein the first plurality of trenches extends inwardly from a first edge of the first metal layer,
wherein the second plurality of trenches extends inwardly from a second edge of the first metal layer, the second edge being orthogonal to the first edge.

20. The power semiconductor module of claim 19, wherein trenches of the first plurality of trenches are spaced apart along the first side of the first metal layer by a first distance, and wherein trenches of the second plurality of trenches are spaced apart along the second side of the first metal layer by a second distance.

21. The power semiconductor module of claim 20, wherein the first distance is equal to the second distance.

22. The power semiconductor module of claim 19, wherein each trench of the first plurality of trenches is isolated from each trench of the second plurality of trenches.

23. The power semiconductor module of claim 19, further comprising:
a further metal layer arranged over a second surface of the electrically insulating layer opposite to the first surface,
wherein the metal layer comprises a circumferential recess separating an inner region and an outer region of the metal layer.

24. A method for producing a power semiconductor module, the method comprising:
providing an electrically insulating layer comprising a first surface;
arranging a first metal layer over the first surface of the electrically insulating layer;
forming a first plurality of trenches in the first metal layer extending inwardly from a first edge of the first metal layer; and
forming a second plurality of trenches in the first metal layer extending inwardly from a second edge of the first metal layer, wherein the second edge is orthogonal to the first edge.

25. The method of claim 24, wherein forming the first plurality of trenches comprises forming the first plurality of trenches by a laser, and wherein forming the second plurality of trenches comprises forming the second plurality of trenches by the laser.
